(19) United States
(12) Patent Application Publication
(10) Pub. No.: US 2002/0079595 A1
(43) Pub. Date: Jun. 27, 2002

(54) Apparatus for connecting a semiconductor die to a substrate and method therefor

(76) Inventors: Burton J. Carpenter, Austin, TX (US); Nhat D. Vo, Austin, TX (US); Christopher T. Clark, Austin, TX (US); Willliam M. Stone, Austin, TX (US); Trent S. Uehling, New Braunfels, TX (US); David B. Clegg, Austin, TX (US)

Correspondence Address: Motorola, Inc., Austin Intellectual Property Law Section, MD: TX32/PL02, 7700 West Parmer Lane, Austin, TX, 78729, US

(21) Appl. No.: 09/746,976

(22) Filed: Dec. 21, 2000

(51) Int. Cl. H01L 23/48; H01L 23/52; H01L 29/40

(52) U.S. Cl. 257/780

(57) ABSTRACT

A pad area of a substrate (50) includes a conductive trace (52) formed on the substrate (50) having a first surface area, the first surface area being of a first solderability. A conductive pad (56) is formed on the first surface area of the conductive trace (52). The conductive pad (56) has a second surface area, the second surface area being of a second solderability. The second solderability is greater than the first solderability. Because of the different solderabilities, a solder bump (46) on the semiconductor die (40) can be reflowed and connected to the second surface area without using a soldermask (28) to contain the melted solder on the second surface area.

### FIELD OF THE INVENTION

This invention relates generally to semiconductor devices, and more particularly, to an apparatus and method for contacting a semiconductor die to a substrate.

### BACKGROUND OF THE INVENTION

In some semiconductor manufacturing processes, such as for example, “flip chip”, bumps are fabricated on pad areas of a semiconductor die in order to interconnect the die to a package or to a substrate. The substrate is used to interface the electrical circuits of the semiconductor die to a printed circuit board.

FIG. 1 illustrates a prior art semiconductor die 10 with a solder bump 16 and a substrate 20 prior to making an electrical connection. There are various ways to form solder bump 16 on semiconductor die 10. In general, a pad 12 is first formed on die 10. A copper stud 14 may then be formed on pad 12 for supporting a solder bump 16. A corresponding pad location is provided on substrate 20. A copper trace 22 is formed on substrate 20 that will cross the pad location. At the designated location on copper trace 22, a pad area is defined. The pad may be prepared by forming a nickel layer 26 on the copper trace 22. A relatively thin gold layer 24 is then formed on the nickel layer 26. A soldermask 28 is formed around the pad area to contain the solder when it is melted so that the liquid solder stays on the pad area and does not wick along the copper trace. Also, the soldermask controls the shape of the bump that helps to maintain a minimum standoff height between the semiconductor die 10 and the substrate 20.

FIG. 2 illustrates the semiconductor die 10 and the pad area of substrate 20 of FIG. 1 after making the electrical connection. To electrically connect semiconductor die 10 to substrate 20, semiconductor die 10 is positioned so that when solder bump 16 is melted, or reflowed, the melted solder will wet the gold layer 24 to form an electrical connection. The shape of the soldermask, the volume of the solder bump, the size of the pad, etc. are important considerations for making a reliable electrical connection that has the minimum standoff height. Note that gold layer 24 has been diffused into the solder bump and therefore is not shown in FIG. 2.

An integrated circuit manufactured using “flip chip” technology may have hundreds of these solder bumps. As the number of bumps on the integrated circuit increases, it is desirable from a cost and die size perspective for the solder connections to be smaller and formed closer together. However, the amount a soldermask opening can be reduced in size is limited by the ability of the soldermask material and process used to resolve at the necessary pad opening size.

Therefore, a need exists to create solder bump connections in semiconductor manufacturing that are reduced in size, pitch, and have good reliability.

### BRIEF DESCRIPTION OF THE DRAWINGS

The present invention is illustrated by way of example and not limited in the accompanying figures, in which like references indicate similar elements, and in which:

FIG. 1 illustrates a prior art semiconductor die with a solder bump and substrate pad area prior to making an electrical connection.

FIG. 2 illustrates the semiconductor die and substrate pad area of FIG. 1 after making the electrical connection.

FIG. 3 illustrates a semiconductor die with a solder bump and substrate pad area prior to making an electrical connection in accordance with the present invention.

FIG. 4 illustrates the semiconductor die and substrate of FIG. 3 after the electrical connection is made.

FIG. 5 illustrates a top-down view of a portion of a substrate in accordance with the present invention.

FIG. 6 illustrates a cross-sectional view of the portion of the substrate of FIG. 5.

### DESCRIPTION OF A PREFERRED EMBODIMENT

Generally, the present invention provides a solder bump structure and a method for forming a bump structure that includes a conductive trace formed on a substrate having a first surface area, the first surface area being of a first solderability. A conductive pad is formed on the first surface area of the conductive trace. The conductive pad has a second surface area, the second surface area being of a second solderability. The second solderability is greater than the first solderability. Because of the different solderabilities, the solder bump on the semiconductor die can be reflowed and connected to the second surface area without using an additional layer to contain the solder on the second surface area.

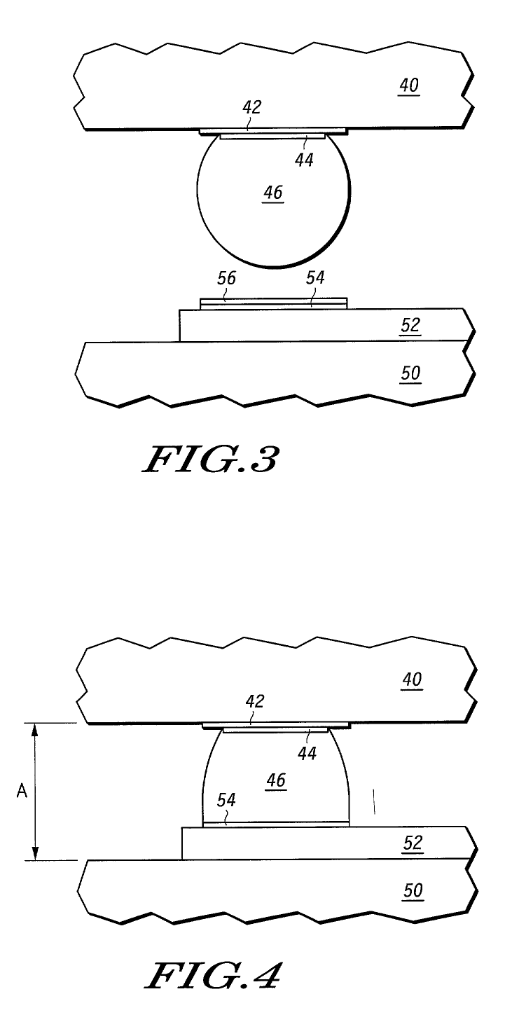

FIG. 3 illustrates a semiconductor die 40 with a eutectic solder bump 46 prior to making an electrical connection with a pad area 56 on substrate 50 in accordance with the present invention. A pad 42 is formed on semiconductor die 40. A copper stud 44 may then be formed on pad 42 for supporting a solder bump 46. In the illustrated embodiment, the solder bump 46 has a diameter of approximately 50 microns. There are various techniques for forming the solder bumps on semiconductor die 40, such as for example, the C4 (Controlled Collapse Chip Connection) bump process, or the E3 (Extended Eutectic Evaporative) bump process, or the like. The method used to form solder bump 46 is not important for purposes of describing the present invention and will not be described further.

In the illustrated embodiment, a dielectric portion of substrate 50 is a conventional substrate formed from an organic material. In other embodiments, substrate 50 may formed from an inorganic material, such as for example, silicon. A pad location is provided on substrate 50 corresponding to the placement of solder bump 46. A copper trace 52 is formed on substrate 50. The copper trace is routed on substrate 50 to transmit electrical signals between the integrated circuits on semiconductor die 40 and a printed circuit board (not shown). In some embodiments, the copper trace may actually be a via formed under the pad area. At a designated location on copper trace 52, the pad area is defined for contacting and electrically connecting with solder bump 46. The pad area is prepared by first forming a nickel layer 54 on the copper trace 52. A gold layer 56 is then formed on the nickel layer 54. Note that in the illustrated embodiment gold is the material used for layer 56. However, in other embodiments, the gold may be replaced with another oxide resistant wettable metal. In addition, the layer 56 may be a mask that is removed when the oxidation of copper trace 52 is complete.

The gold of gold layer 56 has a greater “solderability” than the copper of copper trace 52. For purposes of describing the present invention, the solderability, sometimes known as “wettability”, of a metal is defined as the relative ease in which the metal can be soldered. Generally, gold is known to be easier to solder than copper, therefore, gold has a greater solderability than copper when using the lead-tin solders common in semiconductor manufacturing. In addition, copper is known to more easily form oxides on its surface than gold. The oxides further decrease the solderability of copper, thus requiring the use of a solder flux to help form reliable solder joints. In the illustrated embodiment, the need for a soldermask is eliminated by using conductive layers that have different solderabilities. In addition, the presence of an oxide layer on the surface of, for example, copper trace 52 further increases the difference in solderability between the gold and copper. The oxide layer may simply be a native oxide or an oxide layer deposited or grown on the surface of copper trace 52. Therefore, the solder is less likely to wet the surface of the copper having the oxide, thus effectively forming a dam that inhibits the solder from wicking along trace 52.

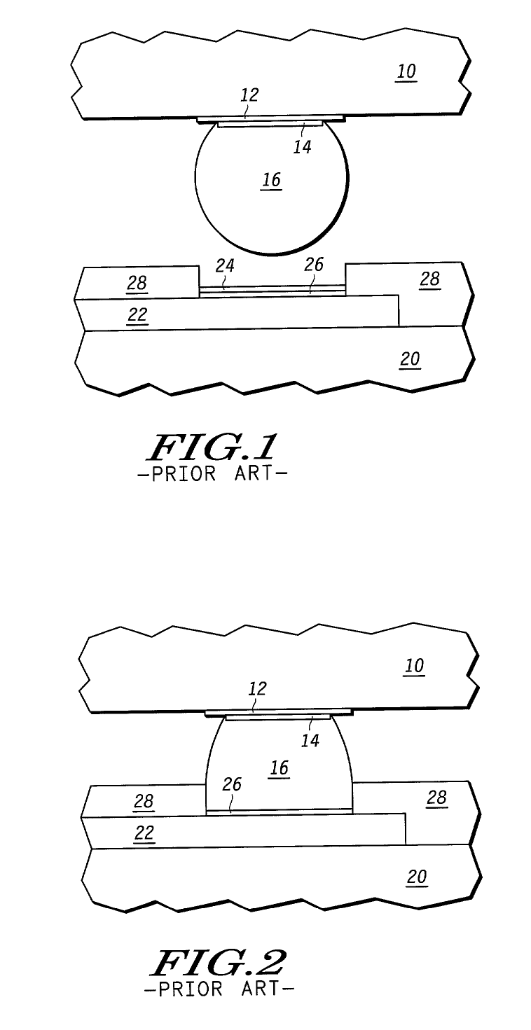

By eliminating the need to use a soldermask, smaller solder pads can be used. Also, the smaller pads can be formed on a smaller pitch. In addition, a smaller pitch allows more densely routed traces across the substrate. In the illustrated embodiment, the solder bumps are about 50 microns in diameter, and a pitch between two adjacent traces is about 100 microns, where “pitch” is defined as the distance between the centers of two substantially parallel traces. Also, eliminating the soldermask layer helps maintain a greater standoff height (labeled “A” in FIG. 4) between the semiconductor die 40 and substrate 50 as compared to the prior art of FIG. 1 and FIG. 2.

FIG. 4 illustrates the semiconductor die 40 and substrate 50 of FIG. 3 after the solder bump is melted, or reflowed, and electrical connection is made between semiconductor die 40 and substrate 50. During the reflow process, gold pad 56 is diffused into the solder bump and disappears as a separate, distinct layer. FIG. 4 illustrates that the difference in solderability between the gold and the native oxides on the copper inhibits solder wicking down copper trace 52, thus providing a reflowed solder bump with adequate standoff height labeled “A”.

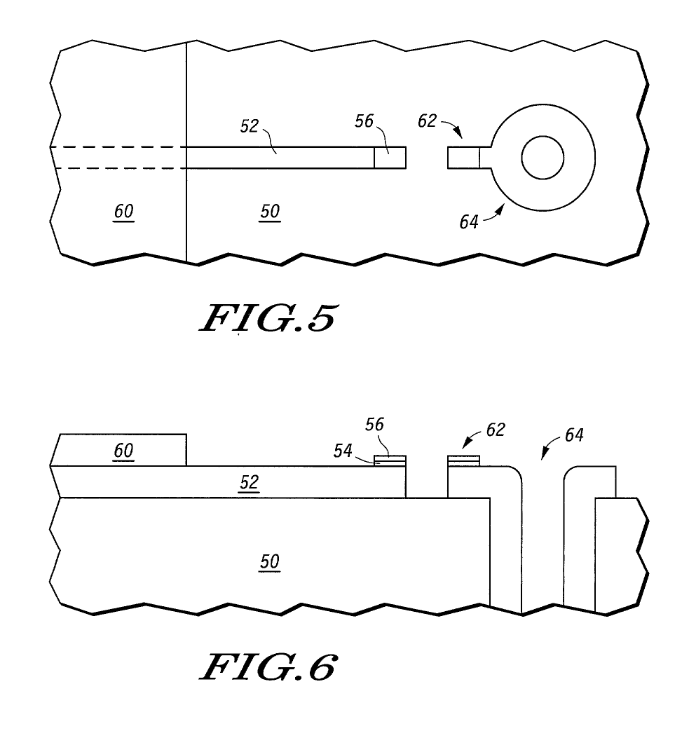

FIG. 5 illustrates a top-down view of a portion of substrate 50 in accordance with one embodiment of the present invention. The gold pad 56 is formed on one end of copper trace 52. In the illustrated embodiment, pad 56 has a generally rectangular shape and a surface area partly defined by the width of copper trace 52. In other embodiments, the shape of pad 56 can be different. Also, for illustration purposes, only one trace 52 is shown, in other embodiments, many traces may be routed substantially parallel to trace 52. Also illustrated in FIG. 5 is another gold pad 62 connected to a via 64. Via 64 is used to provide electrical connection from one metal layer of substrate 50 to another metal layer of substrate 50. Substrate 50 may have many metal layers. Gold pad 62 is formed in a manner similar to gold pad 56. In some embodiments, a soldermask layer 60 may be formed over substrate 50 in an area around the die attach area. Copper trace 52 is shown continuing under soldermask layer 60 as dashed lines. After the semiconductor die is attached to the substrate, an epoxy is used to physically attach the die to the substrate (not shown). The epoxy will cover the bump structures and provide strength and enhance reliability of the connections. When the epoxy is applied to substrate 50, it will cover substrate 50 around the die up to the edge of soldermask layer 60.

FIG. 6 illustrates a cross-sectional view of the portion of the substrate of FIG. 5 on a line along the center of copper trace 52. A semiconductor die (not shown) will be positioned over substrate 50 so that the solder bumps on the die will align with the corresponding pad locations on substrate 50. Depending on the size of the die and the location of the bumps on the die, an edge of the die will be somewhere between pad 56 and soldermask layer 60.

While the invention has been described in the context of a preferred embodiment, it will be apparent to those skilled in the art that the present invention may be modified in numerous ways and may assume many embodiments other than that specifically set out and described above. For example, other metals that have different solderabilities may be used to form the trace and the solder pad instead of copper and gold. Accordingly, it is intended by the appended claims to cover all modifications of the invention which fall within the true scope of the invention.

What is claimed is:

1. An apparatus for interconnecting a semiconductor die to a printed circuit board, comprising:
a substrate;
a conductive trace formed on the substrate having a first surface area, the first surface area being of a first solderability;
a conductive pad formed on the first surface area of the conductive trace having a second surface area, the second surface area being of a second solderability, the second solderability is greater than the first solderability; and
wherein a solder bump on the semiconductor die can be connected to the second surface area without using another material to contain the solder on the second surface area.

2. The apparatus of claim 1, wherein a dielectric portion of the substrate is formed of an organic material.

3. The apparatus of claim 1, wherein the conductive trace comprises copper.

4. The apparatus of claim 1, wherein the conductive pad has a layer that comprises gold.

5. The apparatus of claim 4, wherein the conductive pad has a layer that comprises nickel between the layer comprising gold and the conductive trace.

6. The apparatus of claim 1, wherein the solder bump on the semiconductor die is connected to the second surface area without using a soldermask to contain the solder on the second surface area.

7. The apparatus of claim 1, wherein a native oxide of the first surface area adjacent to the second surface area increases a differential solderability between the first and second surface areas to inhibit the solder from flowing over the first surface area.

8. The apparatus of claim 1, wherein the conductive trace is oxidized to reduce a relative solderability of the conductive trace as compared to conductive pad.

9. The apparatus of claim 1, wherein the second surface area is for connecting to a eutectic tin-lead solder bump.

10. A method for electrically connecting a semiconductor die to a substrate, comprising the steps of:
forming a conductive trace on the substrate, the conductive trace comprising a first metal;
defining a surface area of the conductive trace on which to form a conductive pad; and
forming the conductive pad comprising a second metal, the second metal having greater solderability than the first metal;
wherein a solder bump for electrically connecting the semiconductor die to the substrate, when melted, will not flow onto the first metal.

11. The method of claim 10 wherein the conductive trace is formed of copper.

12. The method of claim 10 wherein the conductive pad is formed using gold plating.

13. The method of claim 10 wherein the step of forming the conductive trace includes forming the conductive trace having a surface comprising a native oxide and the step of forming the conductive pad includes forming the conductive pad of gold.

14. A substrate for supporting a semiconductor die, comprising:
a copper trace for transmitting an electrical signal to or from the semiconductor die;
a gold pad formed on the copper trace, the gold pad for being a solderable connection to the semiconductor; and
wherein a surface of the copper trace has a relatively lower solderability than a surface of the gold pad, thereby allowing a solder bump to be melted and reflowed without the use of a soldermask to contain the solder while the solder is in a liquid state.

15. The substrate of claim 14, wherein a dielectric portion of the substrate is formed from an organic material.

16. The substrate of claim 14, wherein the gold pad has a layer that comprises nickel positioned between the gold pad and the copper trace.

17. The substrate of claim 14, wherein the copper trace includes a native oxide surface layer that increases a differential solderability between the gold pad and the copper trace.

18. The substrate of claim 14, wherein the copper trace is oxidized to have an oxide layer formed on the surface of the copper trace to further reduce solderability of the copper trace.
